(19) United States
(12) Patent Application Publication
(10) Pub. No.: US 2016/0281208 A1
(43) Pub. Date: Sep. 29, 2016

(54) Metal Mask

(71) Applicant: BOE TECHNOLOGY GROUP CO., LTD., Beijing (CN)

(72) Inventor: Peng Zhang, Beijing (CN)

(73) Assignee: BOE Technology Group Co., Ltd., Beijing (CN)

(21) Appl. No.: 14/443,020

(22) PCT Filed: Sep. 30, 2014
(86) PCT No.: PCT/CN2014/087865

§ 371 Date: May 14, 2015

(30) Foreign Application Priority Data
Apr. 29, 2014 (CN) 201410178390.1

(51) Int. Cl. C23C 14/04; C23C 14/24

(52) U.S. Cl. CPC C23C 14/04; C23C 14/24

(57) ABSTRACT

Disclosed is a metal mask configured to act as a mask of a substrate in a vacuum evaporation process. The metal mask comprises a mask pattern and a plurality of alignment openings, wherein an extending direction of the alignment openings in the metal mask is not coincident with a perpendicular direction (M) of a plane where the metal mask is located, and the alignment openings do not penetrate through the metal mask (100). Since the light is reflected for several times and partly absorbed within the alignment openings, images as generated by the CCD system according to the alignment openings of the metal mask and the alignment mark of the substrate have significant color contrast therebetween, thus, they are easily distinguished, which may reduce the alignment difficulty and alignment error.

### TECHNICAL FILED

Embodiments of the present invention relate to a metal mask.

### BACKGROUND

Organic Light Emitting Diode (OLED) has become one of the hot and popular newly developing display products at home and abroad in recent years. The OLED display possesses advantageous such as self-illumination, wide viewing angle, quick response, wide color gamut, low operation voltage, thin panel, manufacturability of flexible panel, and wide temperature range.

Typically, an OLED device is manufactured by utilizing a vacuum evaporation process including heating and evaporating a coating material in vacuum to allow atoms or atomic groups that have been evaporated to be precipitated from a substrate at relatively lower temperature and then form a film. The quality of the film as formed is considerably influenced by the stability of the evaporation process. In order to realize colorful display, it needs to evaporate materials corresponding to the three primary colors, that is, red, green and blue, respectively. One of the typical processes is to use a mask, that is, to arrange a thin metal mask in front of the substrate and to evaporate the materials corresponding to the three primary colors, that is, red, green and blue, at openings of the metal mask only. Since locations where the materials corresponding to the three primary colors, that is, red, green and blue are evaporated (i.e., locations of pixel electrodes) have been accurately defined, the openings of the metal mask have to correspond with the location of the pixel electrode during the evaporation process and no offset thereof beyond an error range is allowed; otherwise, there will be two light-emitting materials overlapping with each other, which may lead to a color mixture. Consequently, an accurate alignment between the substrate and the metal mask is a prerequisite for the evaporation process to be performed.

Typically, the alignment between the substrate and the metal mask is determined through a Charge-Coupled Device (CCD).

### SUMMARY

Embodiments of the present invention provide a metal mask to obtain an easy alignment between a substrate and the metal mask in a vacuum evaporation process with minor alignment error.

At least one embodiment of the present invention provides a metal mask configured to act as a mask of a substrate in a vacuum evaporation process. The metal mask comprises a mask pattern and a plurality of alignment openings. An extending direction of the alignment openings in the metal mask is not coincident with a perpendicular direction of a plane where the metal mask is located and the alignment openings do not penetrate through the metal mask.

In an example of the present invention, an inner wall of the alignment opening is coated with a light absorbing layer.

In an example of the present invention, an included angle between the extending direction of the alignment opening in the metal mask and the perpendicular direction of the plane where the metal mask is located has an absolute value of 15 degree to 45 degree.

In an example of the present invention, the included angle between the extending direction of the alignment opening in the metal mask and the perpendicular direction of the plane where the metal mask is located has an absolute value of 30 degree.

In an example of the present invention, the alignment openings have a same extending direction in the metal mask.

In an example of the present invention, the alignment openings in a same row have a same extending direction in the metal mask or have different extending directions respectively in the metal mask, and the alignment openings in a same column have different extending directions respectively in the metal mask or have a same extending direction in the metal mask; or, the alignment openings arranged diagonally have a same extending direction in the metal mask or have different extending directions respectively in the metal mask.

In an example of the present invention, a cross-section of the alignment opening parallel to the plane where the metal mask is located has a regular geometry shape.

In an example of the present invention, the cross-section of the alignment opening parallel to the plane where the metal mask is located has a round shape.

In an example of the present invention, a space between two end faces of the alignment opening is larger than ⅓ of a thickness of the metal mask.

In an example of the present invention, the light absorbing layer is a coating layer formed of carbon nanotube material.

### BRIEF DESCRIPTION OF THE DRAWINGS

Embodiments of the present invention will be described in more detail below with reference to the accompanying drawings to enable those skilled in the art to understand the present invention more clearly, wherein:

FIG. 1 is a top view of a metal mask as provided by embodiments of the present invention;

FIG. 2 is a sectional view of a metal mask as provided by embodiments of the present invention;

FIG. 3 is a structural view of an alignment opening as provided by embodiments of the present invention;

FIG. 4 is a sectional view of an alignment opening coated with a light absorbing layer on its inner wall as provided by embodiments of the present invention, wherein the section as taken is parallel to the plane where the metal mask is located;

FIG. 5 shows images as generated according to the alignment opening and the alignment mark on the substrate as provided by embodiments of the present invention.

### DETAILED DESCRIPTION

To make objects, technical details and advantages of the embodiments of the invention apparent, technical solutions according to the embodiments of the present invention will be described clearly and completely as below in conjunction with the accompanying drawings of embodiments of the present invention. It is apparent that the described embodiments are only a part of but not all of exemplary embodiments of the present invention. Based on the described embodiments of the present invention, various other embodiments can be obtained by those of ordinary skill in the art without creative labor and those embodiments shall fall into the protection scope of the present invention.

The inventor notices that it is difficult to identify an alignment mark of a substrate and a metal mask in an alignment diagram generated by a CCD system quickly and clearly due to the design of the alignment mark on the metal mask, which leads to difficulty in alignment and relatively large alignment error.

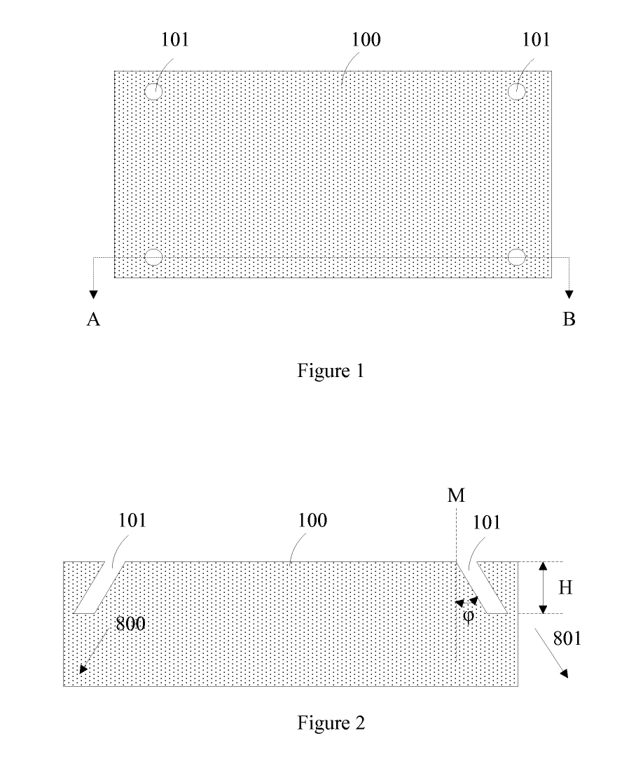

Referring to FIG. 1, an embodiment of the present invention provides a metal mask 100 configured to act as a mask of a substrate in a vacuum evaporation process. The metal mask 100 comprises a mask pattern (not shown) and a plurality of alignment openings 101. An extending direction of the alignment openings 101 in the metal mask 100 is not coincident with a perpendicular direction of a plane where the metal mask 100 is located, and the alignment openings 101 do not penetrate through the metal mask 100.

For example, the substrate can be made of a transparent material, such as glass, quartz, plastic and sapphire.

The light entering the alignment openings 101 will be reflected for several times and absorbed partly within the alignment openings. As a result, images generated by the CCD system according to the alignment opening of the metal mask and the alignment mark of the substrate have relatively significant color contrast therebetween and hence are easily distinguishable.

In an embodiment of the present invention, referring to FIG. 4, an inner wall of the alignment opening 101 is coated with a light absorbing layer 102. According to the present embodiment, coating the inner wall of the alignment opening 101 with the light absorbing layer 102 facilitates light absorption within the alignment opening 101 when performing alignment so that the images generated by the CCD system according to the alignment opening 101 of the metal mask 100 and the alignment mark of the substrate have more significant color contrast therebetween.

For example, the light absorbing layer 102 is a coating layer formed of carbon nanotube material, although the present invention is not limited thereto.

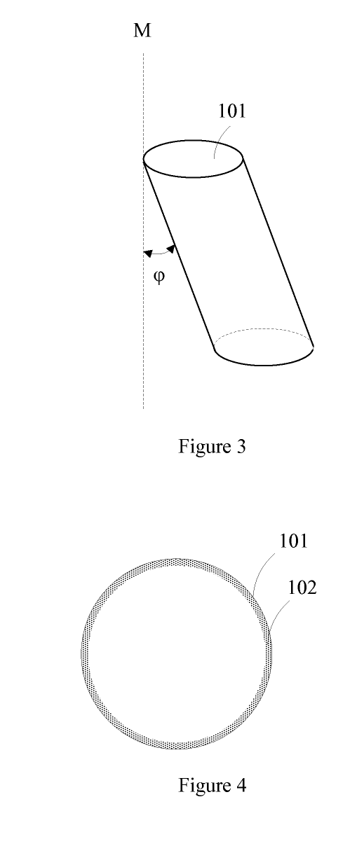

In order to clearly describe the alignment opening 101, FIG. 2 illustrates a cross section of the metal mask taken at location AB in FIG. 1, and FIG. 3 illustrates a structure of the alignment opening 101.

For example, an included angle φ between the extending direction of the alignment opening 101 in the metal mask 100 and the perpendicular direction M of the plane where the metal mask 100 is located has an absolute value of 15 degree to 45 degree. In an embodiment of the present invention, the value of the included angle φ is positive if the extending direction of the alignment opening 101 in the metal mask 100 lies at the right side of the perpendicular direction M of the plane where the metal mask 100 is located; and the value of the included angle φ is negative if the extending direction of the alignment opening 101 in the metal mask 100 lies at the left side of the perpendicular direction M of the plane where the metal mask 100 is located. It's necessary for the included angle φ to be valued within a proper range because an excessively small absolute value of the included angle φ may reduce the opportunity for the light to be reflected within the alignment opening 101, which goes against sufficient light absorption of the light absorbing material, while an excessively large absolute angle may increase the opportunity for the light to be reflected back directly.

For example, the included angle φ between the extending direction of the alignment opening 101 in the metal mask 100 and the perpendicular direction M of the plane where the metal mask 100 is located has an absolute value of 30 degree.

A cross section of the alignment opening 101 parallel to the plane where the metal mask 100 is located can have different shapes, for example, a regular geometry shape, such as round, oval, rectangle, triangle, trapezoid and pentagon, or an irregular geometry shape. It's preferable for the cross section of the alignment opening 101 parallel to the plane where the metal mask 100 is located to have a regular geometry shape. Such a cross section having a regular geometry shape represents a regular alignment opening 101, which allows the light entering the alignment opening 101 to be reflected with high regularity so that the image generated by the alignment opening 101 through the CCD system has uniform color. Otherwise, such a cross section having irregular geometry shape may result in the light being reflected with no regularity, so that the image generated by the alignment opening 101 through the CCD system has dark color in some areas and shallow color in other areas, which may go against the judgment when performing alignment.

It is noted that the cross sections of the plurality of alignment openings 101 parallel to the plane where the metal mask 100 is located shall be identical with each other, that is, these cross sections shall have identical size and identical shape.

For example, the cross section of the alignment hole 101 parallel to the plane where the metal mask 100 is located has a round shape. The alignment opening 101 having a round-shaped cross section allows the light to enter the alignment opening and to be absorbed in a better way so that the image generated by the alignment opening 101 through the CCD system has uniform color.

For example, a space H between two end faces of the alignment opening 101 is larger than ⅓ of a thickness of the metal mask 100. The space H between two end faces of the alignment opening 101 is the vertical depth of the alignment opening 101 with respect to a surface of the metal mask 100 and is also referred to as a height of the alignment opening 101. Thus it can be seen that the alignment opening 101 is not a through hole penetrating through the metal mask 101 but is a half-hole. The space H of the alignment opening 101 is adaptive for the light entering the alignment opening 101 to be reflected for several times so that more light can be absorbed. An excessively shallow alignment opening 101 may go against the light absorption.

The plurality of alignment openings 101 on the metal mask 100 as provided by embodiments of the present invention may have a same extending direction in the metal mask 100 or have different extending directions respectively in the metal mask 100. For example, the alignment openings 101 have a same extending direction in the metal mask 100. For another example, the alignment openings 101 in a same row of the top view of the metal mask 100 have a same extending direction in the metal mask 100, and the alignment openings 101 in a same column of the top view of the metal mask 100 have different extending directions respectively in the metal mask 100. For yet another example, the alignment openings 101 in a same row of the top view of the metal mask 100 have different extending directions respectively in the metal mask 100, and the alignment openings 101 in a same column of the top view of the metal mask 100 have a same extending direction in the metal mask 100. For yet another example, the alignment openings 101 located diagonally in the top view of the metal mask 100 have a same extending direction in the metal mask 100 or different extending directions respectively in the metal mask 100. The expression “have a same extending direction” as used in embodiments of the present invention refers to have a same included angle with the perpendicular direction of the plane where the metal mask is located. The expression “have different extending directions” as used in embodiments of the present invention refers to have different included angles with the perpendicular direction of the plane where the metal mask is located; for example, the included angle can be a positive value or a negative value, or, can have different absolute values.

Reference is made to the metal mask 100 as shown in FIG. 2 for more clear explanation. The alignment openings 101 in a same row have different extending directions 800 and 801. The two different extending directions 800 and 801 are oriented towards two ends of the metal mask 100, respectively; that is, the included angles between the extending directions and the perpendicular direction M of the plane where the metal mask 100 is located involve a positive value and a negative value. The extending directions 800 and 801 may be configured to be the same with each other, or the extending direction of the alignment opening 101 may be configured otherwise according to requirements of design and layout, which details thereof are omitted herein.

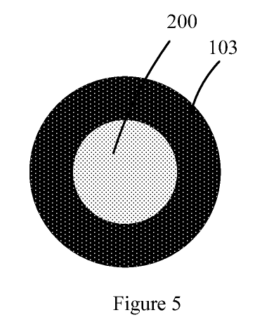

For example, the alignment mark on the substrate is formed into a round shape from metal, and FIG. 5 illustrates images of the alignment opening 101 and the alignment mark on the substrate as generated by the CCD system utilizing the metal mask 100 as provided by embodiments of the present invention under circumstance that the alignment mark has a radius smaller than a radius of the alignment opening 101 of the metal mask 100. The image as generated according to the alignment mark on the substrate is denoted by 200, and the image as generated according to the alignment opening 101 is denoted by 103; obviously, the image 103 and the image 200 have significant color contrast there between.

The extending direction of the alignment openings in the metal mask as provided by embodiments of the present invention is not coincident with the perpendicular direction of the plane where the metal mask is located, and the alignment openings do not penetrate through the metal mask so that the light entering the alignment openings is reflected for several times and absorbed partly within the alignment openings. Furthermore, most part of the light is absorbed by the light absorbing layer coated on the inner wall of the alignment openings. Since part of the light entering the alignment openings is absorbed, the images as generated by the CCD system according to the alignment opening of the metal mask and the alignment mark of the substrate have significant color contrast therebetween, thus, they are easily distinguished, which may reduce the alignment difficulty and alignment error.

It is apparent that an ordinary person in the art can make various variations and modifications to the present invention without departure from the spirit and the scope of the present invention, and if such variations and modifications belong to the claims and equivalent scope of the present invention, the invention is intended to include such variations and modifications.

The present application claims the priority of Chinese patent application No. 201410178390.1 filed on Apr. 29, 2014, which is entirely incorporated herein by reference.

1. A metal mask configured to act as a mask of a substrate in a vacuum evaporation process, the metal mask comprises a mask pattern and a plurality of alignment openings, wherein an extending direction of the alignment openings in the metal mask is not coincident with a perpendicular direction of a plane where the metal mask is located, and the alignment openings do not penetrate through the metal mask.

2. The metal mask according to claim 1, wherein an inner wall of the alignment opening is coated with a light absorbing layer.

3. The metal mask according claim 1, wherein an included angle between the extending direction of the alignment openings in the metal mask and the perpendicular direction of the plane where the metal mask is located has an absolute value of 15 degree to 45 degree.

4. The metal mask according to claim 3, wherein the included angle between the extending direction of the alignment openings in the metal mask and the perpendicular direction of the plane where the metal mask is located has an absolute value of 30 degree.

5. The metal mask according to claim 1, wherein the alignment openings have a same extending direction in the metal mask.

6. The metal mask according to claim 1, wherein the alignment openings in a same row have a same extending direction in the metal mask or have different extending directions respectively in the metal mask, and the alignment openings in a same column have different extending directions respectively in the metal mask or have a same extending direction in the metal mask; or, the alignment openings located diagonally have a same extending direction in the metal mask or have different extending directions respectively in the metal mask.

7. The metal mask according to claim 1, wherein a cross section of the alignment openings parallel to the plane where the metal mask is located has a regular geometry shape.

8. The metal mask according to claim 7, wherein the cross section of the alignment openings parallel to the plane where the metal mask is located has a round shape.

9. The metal mask according to claim 1, wherein a space between two end faces of the alignment openings is larger than ⅓ of a thickness of the metal mask.

10. The metal mask according to claim 2, wherein the light absorbing layer is a coating layer formed of carbon nanotube material.

11. The metal mask according claim 2, wherein an included angle between the extending direction of the alignment openings in the metal mask and the perpendicular direction of the plane where the metal mask is located has an absolute value of 15 degree to 45 degree.

12. The metal mask according to claim 11, wherein the included angle between the extending direction of the alignment openings in the metal mask and the perpendicular direction of the plane where the metal mask is located has an absolute value of 30 degree.

13. The metal mask according to claim 2, wherein the alignment openings have a same extending direction in the metal mask.

14. The metal mask according to claim 3, wherein the alignment openings have a same extending direction in the metal mask.

15. The metal mask according to claim 4, wherein the alignment openings have a same extending direction in the metal mask.

16. The metal mask according to claim 2, wherein the alignment openings in a same row have a same extending direction in the metal mask or have different extending directions respectively in the metal mask, and the alignment openings in a same column have different extending directions respectively in the metal mask or have a same extending direction in the metal mask; or, the alignment openings located diagonally have a same extending direction in the metal mask or have different extending directions respectively in the metal mask.

17. The metal mask according to claim 3, wherein the alignment openings in a same row have a same extending direction in the metal mask or have different extending directions respectively in the metal mask, and the alignment openings in a same column have different extending directions respectively in the metal mask or have a same extending direction in the metal mask; or, the alignment openings located diagonally have a same extending direction in the metal mask or have different extending directions respectively in the metal mask.

18. The metal mask according to claim 3, wherein the alignment openings in a same row have a same extending direction in the metal mask or have different extending directions respectively in the metal mask, and the alignment openings in a same column have different extending directions respectively in the metal mask or have a same extending direction in the metal mask; or, the alignment openings located diagonally have a same extending direction in the metal mask or have different extending directions respectively in the metal mask.

19. The metal mask according to claim 4, wherein the alignment openings in a same row have a same extending direction in the metal mask or have different extending directions respectively in the metal mask, and the alignment openings in a same column have different extending directions respectively in the metal mask or have a same extending direction in the metal mask; or, the alignment openings located diagonally have a same extending direction in the metal mask or have different extending directions respectively in the metal mask.

20. The metal mask according to claim 2, wherein a cross section of the alignment openings parallel to the plane where the metal mask is located has a regular geometry shape.
